(19) United States
(12) Patent Application Publication
(10) Pub. No.: US 2025/0194177 A1
(43) Pub. Date: Jun. 12, 2025

(54) SEMICONDUCTOR DEVICE AND METHOD FOR MANUFACTURING THE SAME

(71) Applicant: SAMSUNG ELECTRONICS CO., LTD., Suwon-si (KR)

(72) Inventors: SANGJUN LEE, Suwon-si (KR); Boram Kim, Suwon-si (KR); Jongseob Kim, Suwon-si (KR); Young Hwan Park, Suwon-si (KR); Jonguk Seo, Suwon-si (KR); Jungseung Yang, Suwon-si (KR); Yongseok Choi, Suwon-si (KR)

(73) Assignee: SAMSUNG ELECTRONICS CO., LTD., Suwon-si (KR)

(21) Appl. No.: 18/748,896

(22) Filed: Jun. 20, 2024

(30) Foreign Application Priority Data
Dec. 7, 2023 (KR) 10-2023-0176899

(51) Int. Cl. H01L 29/06; H01L 29/20; H01L 29/66; H01L 29/778

(52) U.S. Cl. CPC H10D 62/112; H10D 30/015; H10D 30/475; H10D 62/8503

(57) ABSTRACT

A semiconductor device includes a channel layer having a first energy band gap, a barrier layer on the channel layer, the barrier layer including a material having a second energy band gap that is different from the first energy band gap of the channel layer, a gate electrode on the barrier layer, a gate semiconductor layer between the barrier layer and the gate electrode, and at least one dislocation blocking layer in the channel layer, the at least one dislocation blocking layer including a plurality of dislocation blocking patterns extending in the channel layer and in a first direction parallel with a bottom surface of the channel layer, where the plurality of dislocation blocking patterns are arranged at irregular intervals along the first direction.

### CROSS-REFERENCE TO RELATED APPLICATION

This application is based on and claims priority to Korean Patent Application No. 10-2023-0176899, filed on Dec. 7, 2023, in the Korean Intellectual Property Office, the disclosure of which is incorporated by reference herein in its entirety.

### BACKGROUND

Example embodiments of the disclosure relate to a semiconductor device a method for manufacturing a semiconductor device.

The importance of electric power semiconductor devices used in various fields such as transportation fields such as electric vehicles, railways, and electric trams, renewable energy systems such as solar power generation and wind power generation, and mobile devices is gradually increasing. The electric power semiconductor device may refer to a semiconductor device that may be used to handle a high voltage or high current, and performs functions such as electric power conversion and control in a large electric power system or high power electronic device. The electric power semiconductor device may have the ability and durability to handle high electric power, handle large amounts of current, and withstand high voltages. For example, the electric power semiconductor device may handle voltages of hundreds to thousands of volts and currents of tens of amperes to thousands of amperes. The electric power semiconductor device may improve the efficiency of electrical energy by minimizing a power loss. In addition, the electric power semiconductor device may be operated stably even in environments such as high temperature.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device with improved electric characteristics and reliability.

Additional aspects will be set forth in part in the description which follows and, in part, will be apparent from the description, or may be learned by practice of the presented embodiments.

According to an aspect of an example embodiment, a semiconductor device may include a channel layer having a first energy band gap, a barrier layer on the channel layer, the barrier layer including a material having a second energy band gap that is different from the first energy band gap of the channel layer, a gate electrode on the barrier layer, a gate semiconductor layer between the barrier layer and the gate electrode, and at least one dislocation blocking layer in the channel layer, the at least one dislocation blocking layer including a plurality of dislocation blocking patterns extending in the channel layer and in a first direction parallel with a bottom surface of the channel layer, where the plurality of dislocation blocking patterns are arranged at irregular intervals along the first direction.

According to an aspect of an example embodiment, a method of manufacturing a semiconductor device may include forming a channel layer on a substrate, the channel layer having a first energy band gap, forming a barrier layer on the channel layer, the barrier layer including a material with a second energy band gap that is different from the first energy band gap of the channel layer, forming a gate semiconductor layer on the barrier layer, and forming a gate electrode on the gate semiconductor layer, where the forming of the channel layer may include forming a dislocation blocking layer in the channel layer, the dislocation blocking layer including a plurality of dislocation blocking patterns extending in a first direction parallel with a bottom surface of the channel layer and arranged at irregular intervals along the first direction.

According to an aspect of an example embodiment, a semiconductor device may include a substrate, a buffer layer on the substrate, an ultra-lattice layer on the buffer layer, a high-resistance layer on the ultra-lattice layer and including carbon-doped GaN, a channel layer on the high-resistance layer, the channel layer including GaN and having a first energy band gap, a barrier layer on the channel layer, the barrier layer including AlGaN and having a second energy band gap that is different from the first energy band gap of the channel layer, a gate electrode on the barrier layer, a gate semiconductor layer between the barrier layer and the gate electrode, and at least one dislocation blocking layer in the channel layer and including a plurality of dislocation blocking patterns extending in a first direction parallel with a bottom surface of the channel layer, where the plurality of dislocation blocking patterns are arranged at irregular intervals along the first direction, and each dislocation blocking pattern of the plurality of dislocation blocking patterns has a width in a range of about 0.5 nm to about 10 nm.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a semiconductor device according to one or more embodiments;

FIG. 2 is a cross-sectional view illustrating a semiconductor device according to one or more embodiments;

FIG. 3 is an enlarged cross-sectional view illustrating the region A of FIG. 2 according to one or more embodiments;

FIG. 4 is a diagram illustrating a dislocation blocking pattern according to one or more embodiments;

FIG. 5 is a diagram illustrating a dislocation blocking pattern according to one or more embodiments;

FIG. 6 is a diagram illustrating a dislocation blocking pattern according to one or more embodiments;

FIG. 7 is a diagram illustrating a dislocation blocking pattern according to one or more embodiments;

FIG. 8 is a cross-sectional view illustrating a semiconductor device according to one or more embodiments;

FIG. 9 is a cross-sectional view illustrating a semiconductor device according to one or more embodiments; and

FIG. 10 to FIG. 20 are cross-sectional views illustrating a method of manufacturing a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

In addition, the size and thickness of each component shown in the drawing are arbitrarily shown for better understanding and ease of description, and thus the present disclosure is not necessarily limited to what is shown. In the drawings, the thickness of layers, films, panels, regions, etc., are exaggerated for clarity. In addition, in the drawings, the thicknesses of some layers and regions are exaggerated for better understanding and ease of description.

In addition, unless explicitly described to the contrary, the word “comprise”, and variations such as “comprises” or “comprising” will be understood to imply the inclusion of stated elements but not the exclusion of any other elements.

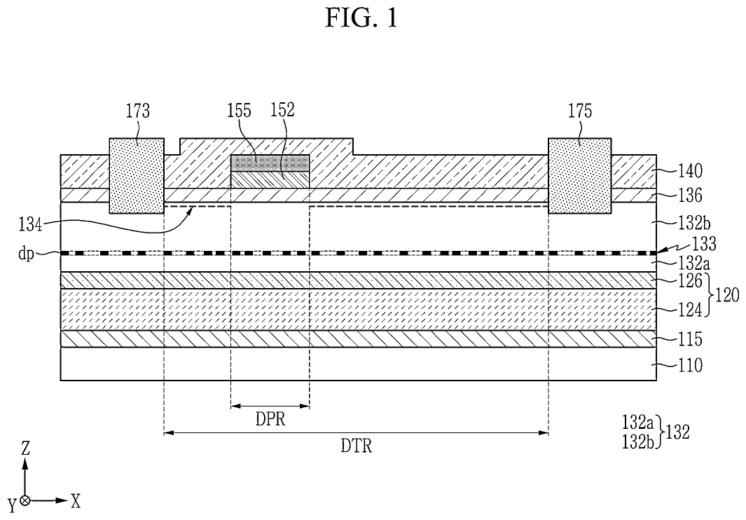

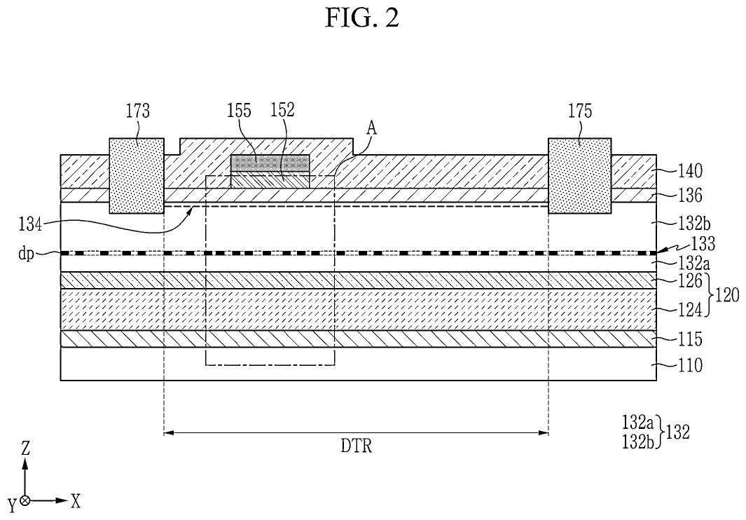

Hereinafter, referring to FIG. 1 and FIG. 2, a semiconductor device according to one or more embodiments will be described.

FIG. 1 is a cross-sectional view illustrating a semiconductor device according to one or more embodiments. FIG. 2 is a cross-sectional view illustrating a semiconductor device according to one or more embodiments. FIG. 1 shows the semiconductor device in an off state according to one or more embodiments, and FIG. 2 shows the semiconductor device in an on state according to one or more embodiments

As shown in FIG. 1, a semiconductor device according to one or more embodiments may include a channel layer 132, a barrier layer 136 disposed on the channel layer 132, a gate electrode 155 disposed on the barrier layer 136, a gate semiconductor layer 152 disposed between the barrier layer 136 and the gate electrode 155, a source electrode 173 and a drain electrode 175 that are disposed to be spaced apart from each other on the channel layer 132, and a dislocation blocking layer 133 disposed in the channel layer 132.

The channel layer 132 may be a layer forming a channel between the source electrode 173 and the drain electrode 175, and a two-dimensional electron gas (2DEG) may be provided inside the channel layer 132. As a charge transport model used in solid physics, the two-dimensional electron gas 134 may refer to a group of electrons that may move freely in two dimensions (e.g., x-y planar direction) but cannot move in another dimension (e.g., z-axis direction) and thus are tightly bound within a dimension. In other words, the 2DEG 134 may exist in a two-dimensional plane within a three-dimensional space. Such a 2DEG 134 mainly appears in a semiconductor heterojunction structure, and may occur at an interface between the channel layer 132 and the barrier layer 136 in the semiconductor device according to one or more embodiments. For example, the 2DEG 134 may be generated in a portion closest to the barrier layer 136 within the channel layer 132.

The channel layer 132 may include one or more materials from Group III-V materials (for example, nitrides containing at least one of Al, Ga, In, or B). The channel layer 132 may be formed of a single layer or multiple layers. The channel layer 132 may be AlₓIn_{y}Ga_{1-x-y}N (0≤x≤1, 0≤y≤1, x+y≤1). For example, the channel layer 132 may include at least one of AlN, GaN, InN, InGaN, AlGaN, AlInN, and AlInGaN. The channel layer 132 may be an impurity doped layer or an impurity undoped layer. A thickness of channel layer 132 may be about several hundred nm or less.

The channel layer 132 may be disposed on a substrate 110, and the buffer layer 120 may be between the substrate 110 and the channel layer 132. The substrate 110 and the buffer layer 120 may be layers necessary to form the channel layer 132, and may be omitted in some cases. For example, when a substrate formed of GaN is used as the channel layer 132, at least one of the substrate 110 and the buffer layer 120 may be omitted. Considering that the price of a substrate formed of GaN is relatively high, the channel layer 132 containing GaN may be grown using the substrate 110 made of Si. In this case, as a lattice structure of Si and a lattice structure of GaN are different, it may not be easy to grow the channel layer 132 directly on the substrate 110. Accordingly, the buffer layer 120 may be grown on the substrate 110 first, and then the channel layer 132 may be grown on the buffer layer 120. In addition, at least one of the substrate 110 and the buffer layer 120 may be removed from a final structure of the semiconductor device after being used in a manufacturing process.

In one or more embodiments, the channel layer 132 may include a dislocation blocking layer 133 therein, which will be described later. The dislocation blocking layer 133 may be disposed at a specific level within the channel layer 132. In one or more embodiments, the channel layer 132 may include a first region 132a disposed below the dislocation blocking layer 133 and a second region 132b disposed above the dislocation blocking layer 133. That is, the dislocation blocking layer 133 may be disposed between the first region 132a and the second region 132b of the channel layer 132. In one or more embodiments, the dislocation blocking layer 133 may be disposed closer to a lower surface of the channel layer 132 in the vertical direction than an upper surface of the channel layer 132, but is not limited thereto. The second region 132b may also be disposed between dislocation blocking patterns dp included in the dislocation blocking layer 133. That is, the second region 132b may surround the sides of the dislocation blocking patterns dp included in the dislocation blocking layer 133. A lower surface of the first region 132a may contact an upper surface of a high-resistance layer 126. An upper surface of the first region 132a may contact the dislocation blocking layer 133. A lower surface of the second region 132b may contact the dislocation blocking layer 133. The upper surface of second region 132b may contact the lower surface of barrier layer 136. The upper surface of the second region 132b may also contact the source electrode 173 or the drain electrode 175, which will be described later.

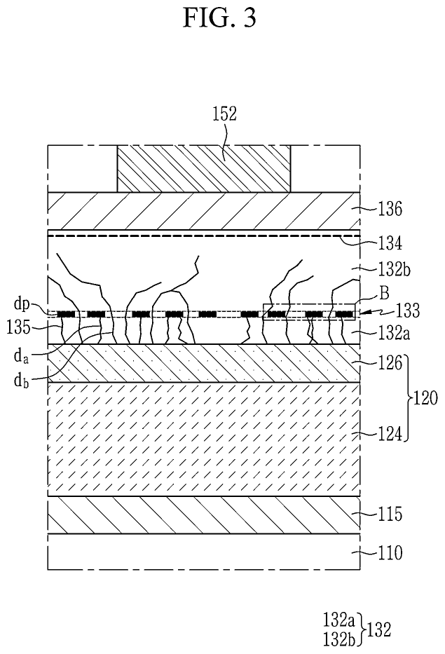

The channel layer 132 may contain defects therein. For example, the channel layer 132 may include dislocations therein (e.g., dislocations 135 of FIG. 3). The dislocations included in the channel layer 132 may be threading dislocations. However, the defects are not limited there to, and the channel layer 132 may include various other types of defects therein. The dislocations may extend, for example, from the bottom of the channel layer 132 to the interior of the channel layer 132. In one or more embodiments, the second region 132b of the channel layer 132 may have a lower defect density as compared to the first region 132a of the channel layer 132. For example, the second region 132b may have a smaller number of threading dislocations included per unit volume as compared to the first region 132a.

The substrate 110 may include a semiconductor material. For example, the substrate 110 may include sapphire, Si, SiC, AlN, GaN, or a combination thereof. The substrate 110 may be a silicon-on insulator (SOI) substrate. However, the material of the substrate 110 is not limited thereto, and any generally-used substrate is applicable. In some cases, the substrate 110 may include an insulating material. For example, several layers including the channel layer 132 may be formed on the semiconductor substrate first, then the semiconductor substrate may be removed and replaced with an insulation substrate.

A seed layer 115 may be disposed on the substrate 110. The seed layer 115 may be disposed directly above the substrate 110. However, the semiconductor device is not limited thereto, and another predetermined layer may be further disposed between the substrate 110 and the seed layer 115. The seed layer 115 may be a layer that serves as a seed for growing the buffer layer 120, which will be described later, and may be made of a crystal lattice structure that becomes the seed of the buffer layer 120. For example, the seed layer may include AlN.

The buffer layer 120 may be disposed directly above the seed layer 115. However, the semiconductor device is not limited thereto, and other predetermined layers may be disposed between the seed layer 115 and the buffer layer 120. The buffer layer 120 may be provided to alleviate a difference in lattice constant and thermal expansion coefficient between the substrate 110 and the channel layer 132. The buffer layer 120 may include one or more materials from Group III-V materials (for example, nitrides containing at least one of Al, Ga, In, or B). The buffer layer 120 may be AlₓIn_{y}Ga_{1-x-y}N (0≤x≤1, 0≤y≤1, x+y≤1). For example, the buffer layer 120 may include at least one of AlN, GaN, InN, InGaN, AlGaN, AlInN, and AlInGaN. The buffer layer 120 may be formed of a single layer or multiple layers. For example, the buffer layer 120 may include an ultra-lattice layer 124 and a high-resistance layer 126 disposed above the ultra-lattice layer 124.

The ultra-lattice layer 124 may be disposed above the seed layer 115. The ultra-lattice layer 124 may be disposed directly on the seed layer 115. However, the semiconductor device is not limited thereto, and other predetermined layers may be disposed between the seed layer 115 and the ultra-lattice layer 124. The ultra-lattice layer 124 may be disposed between the seed layer 115 and the channel layer 132. The ultra-lattice layer 124 may be a layer to alleviate the difference in lattice constant and thermal expansion coefficient between the substrate 110 and the channel layer 132. The ultra-lattice layer 124 may include one or more materials from Group Ill-V materials, such as nitrides containing at least one of Al, Ga, In, or B. The ultra-lattice layer 124 may be AlₓIn_{y}Ga_{1-x-y}N (0≤x≤1, 0≤y≤1, x+y≤1). For example, the ultra-lattice layer 124 may include at least one of AlN, GaN, InN, InGaN, AlGaN, AlInN, and AlInGaN. The ultra-lattice layer 124 may be of a single layer or multiple layers. For example, the ultra-lattice layer 124 may have a structure in which a layer made of AlGaN and a layer made of GaN are repeatedly stacked. For example, AlGaN/GaN/AlGaN/GaN/AlGaN/GaN may be sequentially stacked on the seed layer 115 to form the ultra-lattice layer 124. The number of AlGaN layers and GaN layers that form the ultra-lattice layer 124 may be varied, and the material that form the ultra-lattice layer 124 can be changed in various ways.

The high-resistance layer 126 may be disposed on the ultra-lattice layer 124. The high-resistance layer 126 may be disposed directly on the ultra-lattice layer 124. However, the semiconductor device is not limited thereto, and a predetermined other layer may be further disposed between the ultra-lattice layer 124 and the high-resistance layer 126. The high-resistance layer 126 may be disposed between the ultra-lattice layer 124 and the channel layer 132. The high-resistance layer 126 may prevent the semiconductor device according to one or more embodiments, including the channel layer 132, from being influenced by the outside. The high-resistance layer 126 may be formed of a material with low conductivity such that it may be electrically insulated between the substrate 110 and the channel layer 132. The high-resistance layer 126 may include one or more materials from Group Ill-V materials (for example, nitrides containing at least one of Al, Ga, In, or B). The high-resistance layer 126 may be AlₓIn_{y}Ga_{1-x-y}N (0≤x≤1, 0≤y≤1, x+y≤1). For example, the high-resistance layer 126 may include at least one of AlN, GaN, InN, InGaN, AlGaN, AlInN, and AlInGaN. The high-resistance layer 126 may be formed of a single layer or multiple layers. The high-resistance layer 126 may be a layer in which impurity is not doped. However, the semiconductor device is not limited thereto, and the high-resistance layer 126 may include impurity in addition to the AlₓIn_{y}Ga_{1-x-y}N (0≤x≤1, 0≤y≤1, x+y≤1). For example, the high-resistance layer 126 may include at least one of carbon (C), magnesium (Mg), and iron (Fe) as impurity. The impurity concentration of the high-resistance layer 126 may be different from the impurity concentration of the channel layer 132. For example, the impurity concentration of the high-resistance layer 126 may be greater than the impurity concentration of the first region 132a of the channel layer 132. The high-resistance layer 126 may be impurity doped, and the first region 132a of the channel layer 132 may not be impurity doped. As another example, the impurity concentration of the high-resistance layer 126 may be smaller than the impurity concentration of the first region 132a of the channel layer 132.

In FIG. 1 and FIG. 2, it is illustrated that the buffer layer 120 includes only the ultra-lattice layer 124 and the high-resistance layer 126, but the buffer layer 120 may further include other layers excluding the ultra-lattice layer 124 and the high-resistance layer 126. For example, the buffer layer 120 may further include predetermined other layers disposed between the seed layer 115 and the ultra-lattice layer 124, between the ultra-lattice layer 124 and the high-resistance layer 126, and/or between the high-resistance layer 126 and the channel layer 132.

The barrier layer 136 may be disposed above the channel layer 132. The barrier layer 136 may be disposed directly on the channel layer 132. However, the semiconductor device is not limited thereto, and predetermined other layers may further be disposed between the channel layer 132 and the barrier layer 136. An area of the channel layer 132 that overlaps the barrier layer 136 between the electrodes 173 and 175 may be a drift region DTR. The drift region DTR may be between the source electrode 173 and the drain electrode 175. When a potential difference occurs between the source electrode 173 and the drain electrode 175, carriers may move in the drift region DTR. The semiconductor device according to one or more embodiments may be turned on/off depending on whether a voltage is applied to the gate electrode 155 and the magnitude of the voltage applied to the gate electrode 155, and accordingly, movement of the carrier in the drift region DTR may be achieved or blocked.

The barrier layer 136 may include one or more materials from Group Ill-V materials (for example, nitrides containing at least one of Al, Ga, In, or B). The barrier layer 136 may be AlₓIn_{y}Ga_{1-x-y}N (0≤x≤1, 0≤y≤1, x+y≤1). The barrier layer 136 may include at least one of GaN, InN, AlGaN, AlInN, InGaN, AlN, AlInGaN, and the like. An energy band gap of the barrier layer 136 may be adjusted by a composition ratio of Al and/or In. The barrier layer 136 may be doped with a predetermined impurity. In this case, the impurity doped to the barrier layer 136 may be a P-type dopant that can provide holes. For example, the impurity doped in the barrier layer 136 may be magnesium (Mg). By increasing or decreasing the impurity doping concentration of the barrier layer 136, a threshold voltage, on-resistance, and the like of the semiconductor device according to one or more embodiments may be adjusted.

The barrier layer 136 may include a semiconductor material with characteristics different from those of the channel layer 132. The barrier layer 136 may differ from the channel layer 132 in at least one of polarization characteristic, energy band gap, or lattice constant. For example, the barrier layer 136 may include a material having a different energy band gap than the channel layer 132. In this case, the barrier layer 136 may have a higher energy band gap than the channel layer 132 and may have a higher electrical polarization rate than the channel layer 132. Due to such a barrier layer 136, the 2DEG 134 may be induced in the channel layer 132, which has a relatively low electrical polarization rate. In this respect, the barrier layer 136 may also be referred to as a channel supply layer or a 2DEG supply layer. The 2DEG 134 may be formed within a portion of the channel layer 132 disposed below an interface between the channel layer 132 and the barrier layer 136. The 2DEG 134 may have very high electron mobility.

The barrier layer 136 may be formed of a single layer or multiple layers. When the barrier layer 136 is formed of multiple layers, the energy band gap of the material of each layer constituting the multiple layers may be different. In this case, the various layers constituting the barrier layer 136 may be arranged such that the energy band gap increases as it approaches the channel layer 132.

The gate electrode 155 may be disposed on the barrier layer 136. The gate electrode 155 may overlap with some regions of the barrier layer 136. The gate electrode 155 may overlap with a portion of the drift region DTR of the channel layer 132. That is, the gate electrode 155 may be provided in the drift region DTR. The gate electrode 155 may be disposed between the source electrode 173 and the drain electrode 175. The gate electrode 155 may be spaced apart from the source electrode 173 and the drain electrode 175.

The gate electrode 155 may include a conductive material. For example, the gate electrode 155 may include a metal, a metal alloy, a conductive metal nitride, a metal silicide, a doped semiconductor material, a conductive metal oxide, or a conductive metal oxide. For example, the gate electrode 155 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbo-nitride (TiAlC—N), titanium aluminum carbide (TiAlC), titanium carbide (TiC), tantalum carbo-nitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof. The gate electrode 155 may be formed of a single layer or multiple layers.

The gate semiconductor layer 152 may be disposed between the barrier layer 136 and the gate electrode 155. That is, the gate semiconductor layer 152 may be disposed on the barrier layer 136, and the gate electrode 155 may be disposed on the gate semiconductor layer 152. The gate electrode 155 may ohmic-contact or schottky-contact the gate semiconductor layer 152. The gate electrode 155 may overlap the gate semiconductor layer 152. In this case, the gate semiconductor layer 152 may be completely overlapped by the gate electrode 155 in the vertical direction, and an upper surface of the gate semiconductor layer 152 may be wholly covered by the gate electrode 155. That is, the gate semiconductor layer 152 may have substantially the same planar shape (i.e., width) as the gate electrode 155.

The gate semiconductor layer 152 may be disposed between the source electrode 173 and the drain electrode 175. The gate semiconductor layer 152 may be spaced apart from the source electrode 173 and the drain electrode 175. The gate semiconductor layer 152 may be disposed closer to the source electrode 173 than the drain electrode 175. That is, a distance between the gate semiconductor layer 152 and the source electrode 173 may be smaller than a distance between the gate semiconductor layer 152 and the drain electrode 175.

The gate semiconductor layer 152 may include one or more materials from Group III-V materials (for example, nitrides containing at least one of Al, Ga, In, or B). The gate semiconductor layer 152 may be AlₓIn_{y}Ga_{1-x-y}N (0≤x≤1, 0≤y≤1, x+y≤1). For example, the gate semiconductor layer 152 may include at least one of AlN, GaN, InN, InGaN, AlGaN, AlInN, and AlInGaN. The gate semiconductor layer 152 may include a material having an energy band gap that is different from that of the barrier layer 136. For example, the gate semiconductor layer 152 may include GaN, and the barrier layer 136 may include AlGaN. The gate semiconductor layer 152 may be doped to a predetermined impurity. In this case, the impurity doped in the gate semiconductor layer 152 may be a P-type dopant that may provide holes. For example, the gate semiconductor layer 152 may include GaN doped with P-type impurity. That is, the gate semiconductor layer 152 may be formed of a p-GaN layer. However, the semiconductor device is not limited thereto, and the gate semiconductor layer 152 may be a p-AlGaN layer. The impurity doped in the gate semiconductor layer 152 may be magnesium (Mg). The gate semiconductor layer 152 may be formed of a single layer or multiple layers.

A depletion region DPR may be formed within the channel layer 132 by the gate semiconductor layer 152. The depletion region DPR may be within the drift region DTR and may have a narrower width than the drift region DTR. As the gate semiconductor layer 152, which has a different energy band gap from that of the barrier layer 136, is disposed on the barrier layer 136, a level of the energy band of a portion of the barrier layer 136 that overlaps the gate semiconductor layer 152 may increase. Accordingly, the depletion region DPR may be formed in an area of the channel layer 132 that overlaps the gate semiconductor layer 152. In other words, the width of the depletion region DPR may be defined by the width of the gate semiconductor layer 152. The depletion region DPR may be a region in a channel path of the channel layer 132 where the 2DEG 134 is not formed or has a lower electron concentration than the remaining regions. In other words, the depletion region DPR may refer to a region where the flow of the 2DEG 134 is cut within the drift region DTR. As the depletion region DPR occurs, a current does not flow between the source electrode 173 and the drain electrode 175, and the channel path may be blocked. Accordingly, the semiconductor device according to one or more embodiments may have a normally off characteristic.

That is, the semiconductor device according to one or more embodiments may be a normally off high electron mobility transistor (HEMT). As shown in FIG. 1, in a normal state in which no voltage is applied to the gate electrode 155, a depletion region DPR exists, and the semiconductor device according to one or more embodiments may be in an off state. As shown in FIG. 2, when a voltage higher than the threshold voltage is applied to the gate electrode 155, the depletion region DPR disappears, and the 2DEG 134 within the drift region DTR is connected. That is, the 2DEG 134 may be formed throughout the channel path between the source electrode 173 and the drain electrode 175, and the semiconductor device according to one or more embodiments may be in an on state. In summary, the semiconductor device according to one or more embodiments may include semiconductor layers with different electrical polarization characteristics, and a semiconductor layer with a relatively large polarization rate may cause the 2DEG 134 in another layer connected to another semiconductor layer to be heterogeneously bonded therewith. The 2DEG 134 may be used as a channel between the source electrode 173 and the drain electrode 175, and the continuation or interruption of the flow of the 2DEG 134 may be controlled by a bias voltage applied to the gate electrode 155. In the gate off state, the flow of the 2DEG 134 is blocked, and thus the current may not flow between the source electrode 173 and the drain electrode 175. As the flow of the 2DEG 134 continues in the gate on state, the current may flow between the source electrode 173 and the drain electrode 175.

The dislocation blocking layer 133 may be disposed inside the channel layer 132. In one or more embodiments, the dislocation blocking layer 133 may be disposed at a specific level within the channel layer 132. Referring to FIG. 2, the dislocation blocking layer 133 may be disposed at a predetermined distance from the lower surface of the channel layer 132 in a thickness direction (i.e., the z-direction). For example, the dislocation blocking layer 133 may be disposed at a distance of 50 nm from the lower surface of the channel layer 132 in the thickness direction. However, the position of the dislocation blocking layer 133 in the channel layer 132 is not limited thereto. The dislocation blocking layer 133 may include a plurality of dislocation blocking patterns dp arranged internally to be spaced apart from each other.

The plurality of dislocation blocking patterns dp included in the dislocation blocking layer 133 may be disposed at a specific level within the channel layer 132. Bottom surfaces of the dislocation blocking patterns may be disposed on a plane of the same level. That is, the dislocation blocking patterns dp may have bottom surfaces that are disposed at the same distance from the bottom surface of the channel layer 132 in the thickness direction. Upper surfaces and lower surfaces of the dislocation blocking patterns dp may contact the channel layer 132. All or some of the upper surfaces of the dislocation blocking patterns dp may contact the second region 132b of the channel layer 132. The lower surface of the dislocation blocking patterns dp may contact the first region 132a of the channel layer 132. Side surfaces of the dislocation blocking patterns dp may be surrounded by the second region 132b of the channel layer 132. The upper surface of all or some of the dislocation blocking patterns dp may contact the second region 132b included in the dislocation blocking layer 133.

The plurality of dislocation blocking patterns dp may be spaced apart from each other along a direction parallel to the bottom surface of the channel layer 132. In this case, an interval between the plurality of dislocation blocking patterns dp included in the dislocation blocking layer 133 may not be constant. In other words, the plurality of dislocation blocking patterns dp included in the dislocation blocking layer 133 may be arranged at irregular intervals and spaced apart from each other at varied horizontal (i.e., x-direction) distances on the same level plane in the channel layer 132.

Each of the plurality of dislocation blocking patterns dp included in the dislocation blocking layer 133 may extend in a direction parallel to the bottom surface of the channel layer 132. In this case, a length to which each of the plurality of dislocation blocking patterns dp extends may be several nanometers (nm). In other words, a width of each of the plurality of dislocation blocking patterns dp in a direction parallel to the bottom surface of the channel layer 132 may be several nanometers (nm). In one or more embodiments, the dislocation blocking patterns dp included in the dislocation blocking layer 133 may all have the same width or may have different widths. In one or more embodiments, all or some of the dislocation blocking patterns dp may have different widths in a first direction (X-axis direction) and lengths in a second direction (Y-axis direction). When viewed on a plane parallel to the first direction (X-axis direction) and the second direction (Y-axis direction), all or some of the dislocation blocking patterns dp may have a quadrangle, circular, oval, or irregular shape. In one or more embodiments, at least one of a width in the first direction (X-axis direction) and a length in the second direction (Y-axis direction) of each of the dislocation blocking patterns dp may be about 0.5 nm to about 10 nm, and in one or more embodiments, about 0.5 nm to about 2 nm. Here, the width/length may refer to the maximum dimension in the corresponding direction.

In one or more embodiments, all or some of the dislocation blocking patterns dp may have the same height or different heights. In one or more embodiments, a height of each of the dislocation blocking patterns dp may be less than or equal to about 1 nm. As an example, a height of each dislocation blocking patterns dp may be less than about 0.5 nm to about 1 nm. Here, the height may refer to the maximum height in the third direction (Z-axis direction). In one or more embodiments, each dislocation blocking pattern dp may have a flat upper surface of a plate-like shape, or an upper surface of an irregular shape.

The dislocation blocking patterns dp may include an insulating material. In this case, a material that is easy to be formed within the channel layer 132 during the process of forming the channel layer 132 may be selected as the insulating material. For example, at least one element among the elements constituting the material included in the channel layer 132 may also be included as an element constituting the insulating material included in the dislocation blocking patterns dp. For example, when the channel layer 132 includes nitride, the dislocation blocking patterns dp may also include nitride. In one or more embodiments, when the channel layer 132 includes GaN, the dislocation blocking patterns dp may be a nitride that includes a material other than gallium (Ga) as an element. For example, the dislocation blocking patterns dp may include silicon nitride (SiNₓ). In one or more embodiments, the dislocation blocking patterns dp may be formed in-situ during the process of forming the channel layer 132, in the same process as the process of forming the channel layer 132. In other words, the dislocation blocking patterns dp may be formed by controlling the type and amount of materials implanted into the chamber in the process of forming the channel layer 132. In this case, at least one material among the materials required to form the channel layer 132 may also be used in the process of forming the dislocation blocking patterns dp. For example, when the channel layer 132 includes GaN and the dislocation blocking patterns dp include silicon nitride (SiNₓ), ammonia (NH₃) may be used as a source material in a process of forming the channel layer 132 and a process of forming the dislocation blocking patterns dp. For example, ammonia (NH₃) gas may be used as a source gas in the process of forming the channel layer 132 and the process of forming the dislocation blocking patterns dp.

The dislocation blocking patterns dp may be surrounded by the second region 132b of the channel layer 132. Side surfaces of the dislocation blocking patterns dp may be surrounded by the second region 132b. In one or more embodiments, the second region 132b may contact the upper surface of all or some of the dislocation blocking patterns dp. The second region 132b may fill the remaining region except for areas where the dislocation blocking patterns dp are disposed inside the dislocation blocking layer 133.

The buffer layer 120, the channel layer 132, the dislocation blocking layer 133, the barrier layer 136, and the gate semiconductor layer 152 described above may be sequentially stacked on the substrate 110. In the semiconductor device according to one or more embodiments, at least one of the buffer layer 120, the channel layer 132, the barrier layer 136, or the gate semiconductor layer 152 may be omitted. The buffer layer 120, the channel layer 132, the barrier layer 136, and the gate semiconductor layer 152 may be formed of the same semiconductor material, and a material composition ratio of each layer may be different from one another in consideration of the role of each layer and the performance required for the semiconductor device.

The source electrode 173 and the drain electrode 175 may be disposed on the channel layer 132. The source electrode 173 and the drain electrode 175 may be distanced from each other, and the gate electrode 155 and the gate semiconductor layer 152 may be disposed between the source electrode 173 and the drain electrode 175. The gate electrode 155 and the gate semiconductor layer 152 may be spaced apart from the source electrode 173 and the drain electrode 175. The source electrode 173 may be electrically connected to the channel layer 132 on one side of the gate electrode 155. The drain electrode 175 may be electrically connected to the channel layer 132 on the other side of the gate electrode 155. The source electrode 173 and the drain electrode 175 may be disposed outside the drift region DTR of the channel layer 132. An interface between the source electrode 173 and the channel layer 132 may be one edge of the drift region DTR. Similarly, an interface between the drain electrode 175 and the channel layer 132 may be the other edge of the drift region DTR.

The source electrode 173 and the drain electrode 175 may include a conductive material. For example, the source electrode 173 and the drain electrode 175 may include a metal, a metal alloy, a conductive metal nitride, a metal silicide, a doped semiconductor material, a conductive metal oxide, or a conductive metal oxide. For example, the source electrode 173 and the drain electrode 175 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbo-nitride (TiAlC—N), titanium aluminum carbide (TiAlC), titanium carbide (TiC), tantalum carbo-nitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof. The source electrode 173 and the drain electrode 175 may be formed of a single layer or multiple layers. The source electrode 173 and the drain electrode 175 may ohmic-contact the channel layer 132. A region in contacting the source electrode 173 and the drain electrode 175 within the channel layer 132 may be doped at a relatively high concentration compared to other regions.

The semiconductor device according to one or more embodiments may include a first protective layer 140 covering upper surfaces of the barrier layer 136 and the gate electrode 155. The first protective layer 140 may cover side surfaces the gate semiconductor layer 152 and the gate electrode 155. The first protective layer 140 may cover a portion of the side surface of the source electrode 173 and a portion of the side surface of the drain electrode 175. A bottom surface of the first protective layer 140 may be contact the barrier layer 136 and the gate electrode 155.

The first protective layer 140 may include an insulating material. For example, the first protective layer 140 may include a material such as SiO₂, SiN, SiON, Al₂O₃, and the like. The first protective layer 140 may be formed of a single layer or multiple layers. The first protective layer 140 may include a first lower protective layer and a second upper protective layer. In some cases, the first protective layer 140 may include three or more layers.

FIG. 3 is an enlarged cross-sectional view illustrating the region A of FIG. 2 according to one or more embodiments.

Referring to FIG. 3, the semiconductor device according to one or more embodiments may include the dislocation blocking layer 133 formed in the channel layer 132. The dislocation blocking layer 133 may be disposed at a specific level within the channel layer 132. The dislocation blocking layer 133 may include a plurality of dislocation blocking patterns dp arranged to be spaced apart from each other. In one or more embodiments, the dislocation blocking patterns dp may be arranged at irregular intervals, such that the patterns dp are spaced apart from each other at varied distances along a direction parallel to the bottom surface of the channel layer 132.

A thickness of the channel layer 132 may be appropriately selected considering the dislocation density in a region adjacent to the channel layer 132 flatness of the upper surface of the channel layer 132, a process time, and the like. When dislocation blocking patterns dp are included within the channel layer 132, such as in the semiconductor device according to one or more embodiments, the second region 132b of the channel layer 132 may be required to be formed to have a certain thickness or more such that the upper surface of the channel layer 132 may be sufficiently flat. However, when the thickness of the second region 132b is too thick, the process time may increase excessively. In one or more embodiments, the second region 132b may have a thickness of about 50 nm to about 450 nm.

The channel layer 132 may include a plurality of dislocations 135 formed therein. For example, the plurality of dislocations 135 formed inside the channel layer 132 may be threading dislocations. However, the type of defect inside the channel layer 132 is not limited. Referring to FIG. 3, the dislocations 135 may be formed from the bottom surface of the channel layer 132 and extend into the interior of the channel layer 132. Specifically, the dislocations 135 may propagate from the bottom of the channel layer 132 to the inside of the first region 132a. Some of the dislocations 135 propagating inside the first region 132a of the channel layer 132 may penetrate the dislocation blocking layer 133 and further propagate inside the second region 132b of the channel layer 132. Other dislocations 135 extending inside the first region 132a of the channel layer 132 may have one end contacting the bottom surface of the dislocation blocking patterns dp included in the dislocation blocking layer 133.

Among the dislocations 135 included in the first region 132a, dislocations 135 that contact the dislocation blocking patterns dp may not propagate into the second region 132b of the channel layer 132. For example, in the case of dislocation dₐ shown in FIG. 3, dislocation dₐ may propagate into the first region 132a from the bottom surface of the channel layer 132 and then may meet the bottom surface of the dislocation blocking patterns dp. In this case, the dislocations such as dislocation dₐ may no longer propagate to other regions within the channel layer 132. Accordingly, the second region 132b of the channel layer 132 may have a lower dislocation density compared to the first region 132a.

Among the dislocations 135 included the first region 132a, in the case of the dislocations 135 that do not contact the dislocation blocking patterns dp, the direction in which the dislocations 135 propagates may change. When the plurality of dislocation blocking patterns dp are disposed inside the channel layer 132, the channel layer 132 may not be grown on the upper surface of the dislocation blocking patterns dp. Accordingly, the channel layer 132 may not grow in an upward direction with reference to the bottom surface of the channel layer 132, but may grow in a lateral direction of the channel layer 132. In this case, the direction in which the dislocations 135 included within the channel layer 132 propagate may also change to the side direction of the channel layer 132. For example, in the case of dislocation d_{b} shown in FIG. 3, the dislocation d_{b} propagates from the bottom surface of the channel layer 132 toward the upper surface of the channel layer 132, and then the propagation direction may be changed to the lateral direction of the channel layer 132 at a position adjacent to the dislocation blocking patterns dp. Due to the dislocation blocking patterns dp, the number of dislocations 135 that cannot propagate to the upper surface of the channel layer 132 may increase, and accordingly, the dislocation density at the interface between the channel layer 132 and the barrier layer 136 may decrease.

In a semiconductor device having the same or similar structure described with reference to FIG. 1 to 3, the 2DEG 134 may be disposed at an interface between the channel layer 132 and the barrier layer 136. The 2DEG 134 may provide a passage through which electrons flow when the semiconductor device is turned on. Therefore, at the interface between the channel layer 132 and the barrier layer 136, the electric characteristic of the semiconductor device may be deteriorated when the density of defects, such as dislocations 135 described with reference to FIG. 3, is high. In the case of the semiconductor device according to one or more embodiments, the dislocation density at the interface between the channel layer 132 and the barrier layer 136 may be reduced, and thus the electric characteristic of the semiconductor device may be improved.

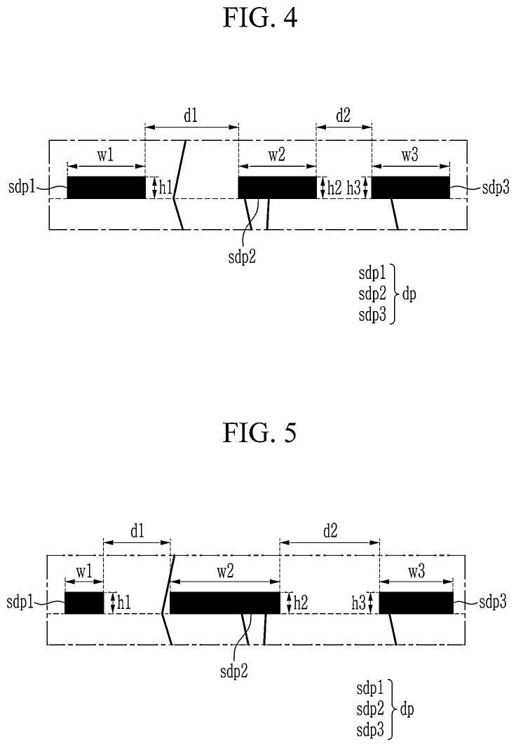

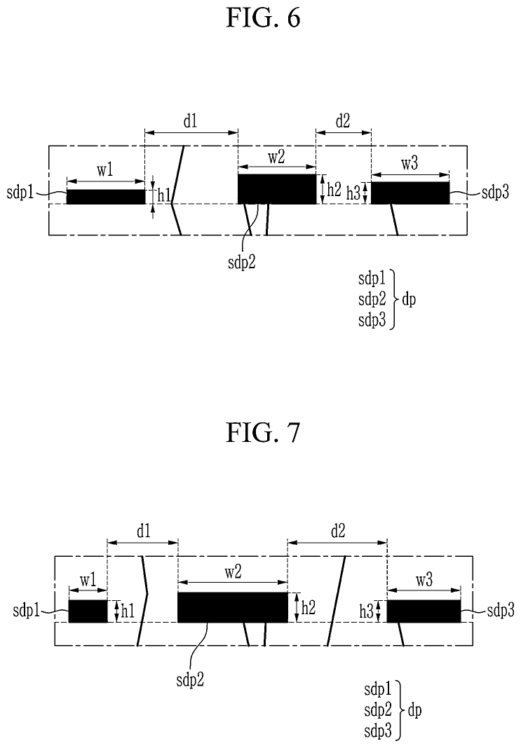

FIG. 4 is a diagram illustrating a dislocation blocking pattern according to one or more embodiments. FIG. 5 is a diagram illustrating a dislocation blocking pattern according to one or more embodiments. FIG. 6 is a diagram illustrating a dislocation blocking pattern according to one or more embodiments. FIG. 7 is a diagram illustrating a dislocation blocking pattern according to one or more embodiments.

FIG. 4 to FIG. 7 show a dislocation blocking pattern according to some embodiments in detail. Specifically, FIG. 4 to FIG. 7 are enlarged cross-sectional views of the region B of FIG. 3. FIG. 4 to FIG. 7 illustrate a first sub-pattern sdp1, a second sub-pattern sdp2, and a third sub-pattern sdp3, which are included in the dislocation blocking patterns dp.

As described with reference to FIG. 1 to FIG. 3, the dislocation blocking patterns dp may be arranged at irregular intervals, such that a distance between dislocation blocking patterns dp may be varied. That is, a distance between first two adjacent dislocation blocking patterns dp may be different from a distance between second two adjacent dislocation blocking patterns. The intervals between the plurality of dislocation blocking patterns dp included in the dislocation blocking layer 133 may be different from each other. For example, referring to FIG. 4 to FIG. 7, an interval d1 between the first sub-pattern sdp1 and the second sub-pattern sdp2 and an interval d2 between the second sub-pattern sdp2 and the third sub-pattern sdp3 may be different from each other. However, the semiconductor device is not limited thereto, and the interval d1 between the first sub-pattern sdp1 and the second sub-pattern sdp2 and the interval d2 between the second sub-pattern sdp2 and the third sub-pattern sdp3 may be substantially the same.

In one or more embodiments, sizes of dislocation blocking patterns dp may be substantially the same. That is, referring to FIG. 4, the dislocation blocking patterns dp may have substantially the same width and height. Specifically, as shown in FIG. 4, a width w1 of the first sub-pattern sdp1, a width w2 of the second sub-pattern sdp2, and a width w3 of the third sub-pattern sdp3 may be the same. In addition, as shown in FIG. 4, a height h1 of the first sub-pattern sdp1, a height h2 of the second sub-pattern sdp2, and a height h3 of the third sub-pattern sdp3 may be substantially the same.

In one or more embodiments, the widths of the dislocation blocking patterns dp may be different and the heights may be substantially the same. Specifically, as shown in FIG. 5, a width w1 of the first sub-pattern sdp1, a width w2 of the second sub-pattern sdp2, and a width w3 of the third sub-pattern sdp3 may be different from each other. In addition, as shown in FIG. 5, a height h1 of the first sub-pattern sdp1, a height h2 of the second sub-pattern sdp2, and a height h3 of the third sub-pattern sdp3 may be substantially the same.

In one or more embodiments, the dislocation blocking patterns dp may have same widths and different heights. Specifically, as shown in FIG. 6, a width w1 of the first sub-pattern sdp1, a width w2 of the second sub-pattern sdp2, and a width w3 of the third sub-pattern sdp3 may be substantially the same. In addition, as shown in FIG. 6, a height h1 of the first sub-pattern sdp1, a height h2 of the second sub-pattern sdp2, and a height h3 of the third sub-pattern sdp3 may be different from each other.

In one or more embodiments, the dislocation blocking patterns dp may have different widths and different heights. Specifically, as shown in FIG. 7, a width w1 of the first sub-pattern sdp1, a width w2 of the second sub-pattern sdp2, and a width w3 of the third sub-pattern sdp3 may be different from each other. In addition, as shown in FIG. 7, a height h1 of the first sub-pattern sdp1, a height h2 of the second sub-pattern sdp2, and a height h3 of the third sub-pattern sdp3 may be different from each other.

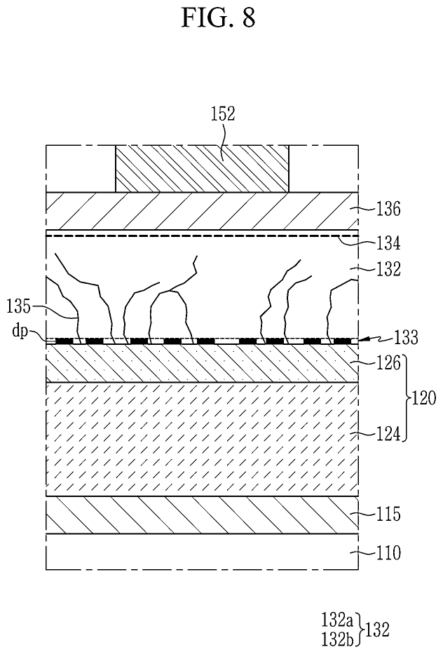

FIG. 8 is a cross-sectional view illustrating a semiconductor device according to one or more embodiments. One or more embodiments shown in FIG. 8 includes features that are the same or similar to those shown in FIG. 1 to FIG. 3, and therefore a description thereof may be omitted. In FIG. 8, the position of the dislocation blocking layer 133 in the channel layer 132 may be different compared to the above-described embodiment.

Referring to FIG. 8, in one or more embodiments, a dislocation blocking layer 133 may be disposed between a channel layer 132 and a high-resistance layer 126. The upper surface of the dislocation blocking layer 133 may contact the lower surface of the channel layer 132, and the lower surface of the dislocation blocking layer 133 may contact the upper surface of the high-resistance layer 126. That is, in one or more embodiments, the dislocation blocking layer 133 may be disposed directly above the high-resistance layer 126.

A thickness of the channel layer 132 may be appropriately selected considering the dislocation density in a region adjacent to the channel layer 132, flatness of the upper surface of the channel layer 132, a process time, and the like. In particular, in order to improve the flatness of the upper surface of the channel layer 132, it may be advantageous to form dislocation blocking patterns dp at the beginning of the process of forming the channel layer 132. As shown in FIG. 8, when the dislocation blocking layer 133 including the dislocation blocking patterns dp is disposed directly on the high-resistance layer 126, the flatness of the upper surface of the channel layer 132 may be improved.

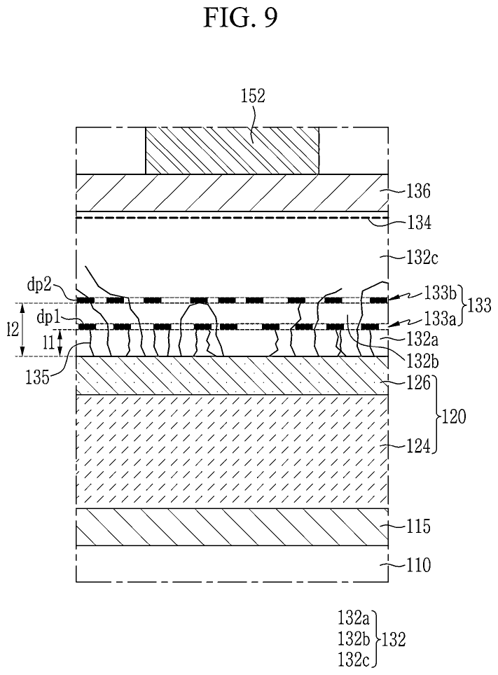

FIG. 9 is a cross-sectional view illustrating a semiconductor device according to one or more embodiments. Aspects of FIG. 9 may be the same or similar to those shown in FIG. 1 to FIG. 3, and therefore a repeated description thereof may be omitted. In FIG. 9, the number of dislocation blocking layers 133 included in a channel layer 132 is varied.

Referring to FIG. 9, a semiconductor device according to one or more embodiments may include two dislocation blocking layers 133 disposed in different levels in the channel layer 132. However, the number of dislocation blocking layers 133a and 133b disposed within the channel layer 132 is not limited by the embodiment. For example, the channel layer 132 may include three or more dislocation blocking layers 133. In one or more embodiments, when the channel layer 132 includes two or more dislocation blocking layers 133, the dislocation blocking layer 133 disposed on top may be disposed closer to a lower surface of the channel layer 132 in the vertical direction than an upper surface of the channel layer 132.

Referring to FIG. 9, the channel layer 132 may include a first dislocation blocking layer 133a disposed at a first level 11 with respect to the bottom surface of the channel layer 132, and a second dislocation blocking layer 133b disposed at a second level 12 with respect to the bottom surface of the channel layer 132. In one or more embodiments, among the two dislocation blocking layers 133a and 133b, the second dislocation blocking layer 133b disposed on top may be disposed closer to the lower surface of the channel layer 132 in the vertical direction than the upper surface of the channel layer 132. In one or more embodiments, the second level 12 may be a higher position than the first level 11 within the channel layer 132. The first dislocation blocking layer 133a may include a plurality of first dislocation blocking patterns dp1 that are arranged at irregular intervals and thus spaced apart from each other at varied distances along a direction parallel to the bottom surface of the channel layer 132. The second dislocation blocking layer 133b may include a plurality of second dislocation blocking patterns dp2 arranged at irregular intervals and thus spaced apart from each other at varied distances along a direction parallel to the bottom surface of the channel layer 132.

The channel layer 132 may include a first region 132a, a second region 132b, and a third region 132c. The first region 132a may be disposed between an upper surface of a high-resistance layer 126 and the first dislocation blocking layer 133a. The second region 132b may be disposed between the first dislocation blocking layer 133a and a second dislocation blocking layer 133b. The second region 132b may also be disposed between the first dislocation blocking patterns dp1 included in the first dislocation blocking layer 133a. That is, the second region 132b may surround side surfaces of the first dislocation blocking patterns dp1 included in the first dislocation blocking layer 133a. The third region 132c may be disposed between the second dislocation blocking layer 133b and a barrier layer 136. The third region 132c may also be disposed between second dislocation blocking patterns dp2 included in the second dislocation blocking layer 133b. That is, the third region 132c may surround side surfaces of the second dislocation blocking patterns dp2 included in the second dislocation blocking layer 133b.

According to one or more embodiments, some of dislocations 135 that penetrate the first dislocation blocking layer 133a and propagate inside the second region 132b may contact a bottom surface of the second dislocation blocking patterns dp2 disposed in the second dislocation blocking layer 133b. In this case, the dislocations 135 that contact the second dislocation blocking patterns dp2 may no longer propagate to other regions within the channel layer 132. Accordingly, the third region 132c of the channel layer 132 may have a lower dislocation density compared to the second region 132b. According to one or more embodiments, the third region 132c, the second region 132b, and the first region 132a may have lower dislocation density in that order. That is, the second region 132b may have a lower dislocation density than the first region 132a, and the third region 132c may have a lower dislocation density than the second region 132b.

In the case of the semiconductor device shown in FIG. 9, the dislocation density at an interface between the channel layer 132 and the barrier layer 136 may be further reduced, and thus the electric characteristic of the semiconductor device can be further improved.

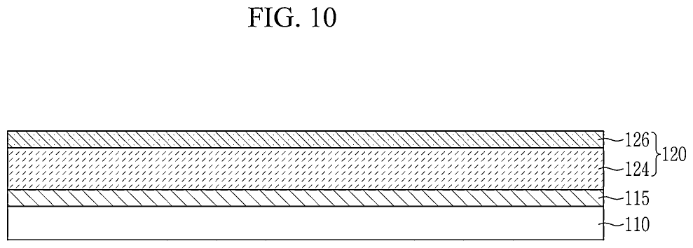

Next, referring to FIG. 10 to FIG. 20, a method of manufacturing a semiconductor device according to one or more embodiments will be described.

FIG. 10 to FIG. 20 are cross-sectional views illustrating a method of manufacturing a semiconductor device according to one or more embodiments.

As shown in FIG. 10, a seed layer 115 and a buffer layer 120 may be sequentially formed on a substrate 110. The buffer layer 120 may include an ultra-lattice layer 124 and a high-resistance layer 126.

The substrate 110 may include a semiconductor material. For example, the substrate 110 may include sapphire, Si, SiC, AlN, GaN, or a combination thereof. The substrate 110 may be an SOI substrate. However, the material of the substrate 110 is not limited thereto, and any generally-used substrate may be applicable.

The seed layer 115 may be formed on the substrate 110. In a final structure of the semiconductor device according to one or more embodiments, the seed layer 115 may be disposed between the substrate 110 and the buffer layer 120. The seed layer 115 may be a layer that serves as a seed for growing the buffer layer 120, and may be formed of a crystal lattice structure that becomes the seed of the buffer layer 120.

The buffer layer 120 may be formed. Specifically, the ultra-lattice layer 124 and the high-resistance layer 126 may be formed sequentially on the seed layer 115. The ultra-lattice layer 124 and the high-resistance layer 126 may be formed sequentially using an epitaxial growth method. The ultra-lattice layer 124 may be formed first on the seed layer 115, and the high-resistance layer 126 may be formed on the ultra-lattice layer 124. The ultra-lattice layer 124 and the high-resistance layer 126 may be formed of the same-based semiconductor material. However, a material formation ratio of each layer may be different considering the role of each layer and the performance required for the semiconductor device. The ultra-lattice layer 124 and the high-resistance layer 126 may include one or more materials from Group III-V materials (for example, nitrides containing at least one of Al, Ga, In, or B). The ultra-lattice layer 124 and the high-resistance layer 126 may be AlₓIn_{y}Ga_{1-x-y}N (0≤x≤1, 0≤y≤1, x+y≤1). For example, the buffer layer 120, the ultra-lattice layer 124, and the high-resistance layer 126 may include at least one of AlN, GaN, InN, InGaN, AlGaN, AlInN, and AlInGaN. As an example, the substrate 110 includes Si, the seed layer 115 includes AlN, and the ultra-lattice layer 124 may have a structure in which a layer made of AlGaN and a layer made of GaN are repeatedly stacked. The high-resistance layer 126 may include GaN. The ultra-lattice layer 124 may or may not be impurity doped.

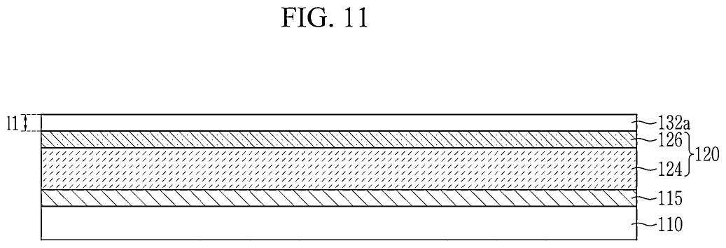

The channel layer 132 may be formed on the high-resistance layer 126 as shown in FIG. 11 to FIG. 14. As the lattice structure of Si and the lattice structure of GaN are different, it may not be easy to grow the channel layer 132 made of GaN directly on the substrate 110 that is made of Si. In the method of manufacturing the semiconductor device according to one or more embodiments, the buffer layer 120 is formed first on the substrate 110 and then the channel layer 132 is formed such that the lattice structure of the channel layer 132 can be stably formed. In one or more embodiments, the channel layer 132 may include a first region 132a, a second region 132b, and a third region 132c.

First, referring to FIG. 11, the first region 132a may be formed on the high-resistance layer 126. The first region 132a may be grown to a first level 11 with reference to an upper surface of the high-resistance layer 126. In one or more embodiments, the first level 11 may be approximately 50 nm.

The first region 132a may include the same material as the buffer layer 120 described above. That is, the first region 132a may include one or more materials from Group Ill-V materials (for example, nitrides containing at least one of Al, Ga, In, or B). The material included in the first region 132a may be AlₓIn_{y}Ga_{1-x-y}N (0≤x≤1, 0≤y≤1, x+y≤1). For example, the first region 132a may include at least one of AlN, GaN, InN, InGaN, AlGaN, AlInN, and AlInGaN.

The first region 132a may be formed directly on the high-resistance layer 126 using an epitaxial growth method. For example, the first region 132a may be formed by metal organic chemical vapor deposition (MOCVD), molecular beam epitaxy (MBE), or atomic layer deposition (ALD). However, the method in which the first region 132a is formed is not limited to the thin film growth method listed above, and the first region 132a may be formed using various thin film growth methods. The first region 132a may be grown by implanting one or more source materials and one or more precursors in a chamber with predetermined temperature and pressure conditions. For example, when the material included in the first region 132a is GaN, trimethyl gallium (TMGa) and ammonia (NH₃) gas may be implanted into the chamber to form the first region 132a. For example, GaN can be formed by a chemical reaction Formula (1) below.

Ga CH₃₃+NH₃→GaN+3CH₄ (1)

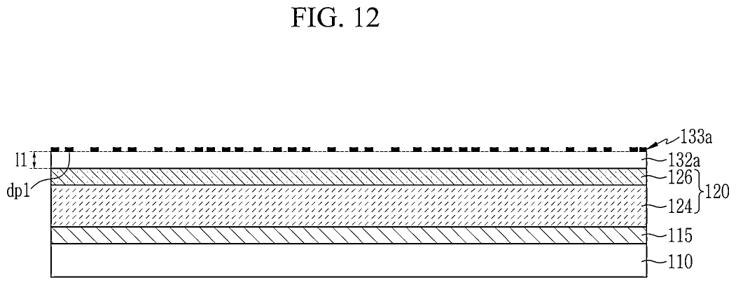

Next, as shown in FIG. 12, the first dislocation blocking layer 133a may be formed on the first region 132a. The first dislocation blocking layer 133a may include first dislocation blocking patterns dp1.

The first dislocation blocking patterns dp1 may be formed on the first region 132a. The first dislocation blocking patterns dp1 may be formed on the upper surface of the first region 132a. The first dislocation blocking patterns dp1 may be arranged at irregular intervals and spaced apart from each other at varied distances along a direction parallel to the bottom surface of the first region 132a.

In one or more embodiments, the first dislocation blocking patterns dp1 may include an insulating material. Among elements constituting the material included in the first region 132a, at least one element may also be included as an element constituting the insulating material included in the first dislocation blocking patterns dp1. In one or more embodiments, when the first region 132a includes GaN, the first dislocation blocking patterns dp1 may be nitride including other materials excluding gallium (Ga) as elements. For example, the first dislocation blocking patterns dp1 may include SiNₓ. In one or more embodiments, the first dislocation blocking patterns dp1 may be formed in-situ in the same process as the process for forming the first region 132a. In other words, the first dislocation blocking patterns dp1 may be formed in a continuous process with the first region 132a within the same chamber (i.e., without moving the position of the semiconductor device being manufactured) immediately after forming the first region 132a. In this case, at least one material among the materials used to form the first region 132a may also be used in the process of forming the first dislocation blocking patterns dp1. For example, when the first region 132a contains GaN and the first dislocation blocking patterns dp1 contains SiNₓ, silane (SiH₄) gas and ammonia (NH₃) gas may be implanted to form the first dislocation blocking patterns dp1. In this case, tri-methyl gallium (TMGa) used to form the first region 132a may not be implanted into the chamber.

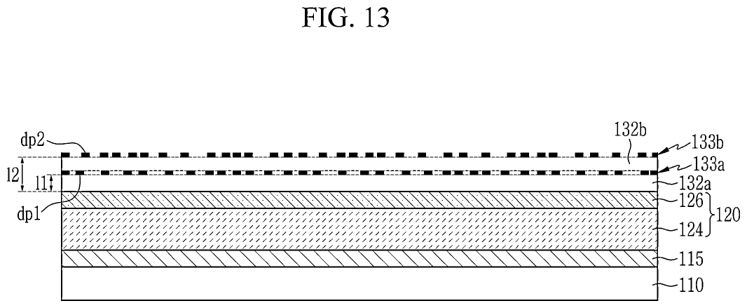

As shown in FIG. 13, the second region 132b of the channel layer 132 and the second dislocation blocking layer 133b may be sequentially formed on the first region 132a and the first dislocation blocking layer 133a. The second region 132b may also be formed between the first dislocation blocking patterns dp1.

The second region 132b may be formed to a second level 12 with respect to the upper surface of the high-resistance layer 126. The second level 12 may be higher than first level 11. In one or more embodiments, the second level may be approximately 100 nm.

The second region 132b may include the same material as the first region 132a. That is, the second region 132b may include may include one or more materials from Group III-V materials (for example, nitrides containing at least one of Al, Ga, In, or B). The material included in the second region 132b may be AlₓIn_{y}Ga_{1-x-y}N (0≤x≤1, 0≤y≤1, x+y≤1). For example, the first region 132a may include at least one of AlN, GaN, InN, InGaN, AlGaN, AlInN, and AlInGaN.

The second region 132b may be formed on the first region 132a and the first dislocation blocking layer 133a using an epitaxial growth method. The second region 132b may be grown in the same way as the first region 132a. In one or more embodiments, the second region 132b may be formed in-situ in the same process as the process forming the first region 132a and the first dislocation blocking layer 133a. Among the entire upper surface region of the first region 132a, a portion exposed between the first dislocation blocking patterns dp1 may be used as a seed to form the second region 132b. In other words, the material (e.g., GaN) included in the second region 132b may be grown from the upper surface of the first region 132a. However, the material (e.g., GaN) included in the second region 132b may not grow in an area covered by the first dislocation blocking patterns dp1. Accordingly, the material included in the second region 132b may not grow in the upward direction, but may grow in the lateral direction in a region adjacent to the first dislocation blocking patterns dp1. In this case, a direction in which the dislocations contained within the second region 132b propagate may also change to the lateral direction.

Subsequently, the second dislocation blocking layer 133b may be formed on the second region 132b. The second dislocation blocking layer 133b may include second dislocation blocking patterns dp2.

The second dislocation blocking patterns dp2 may be formed on the upper surface of the second region 132b. The second dislocation blocking patterns dp2 may be arranged at irregular intervals and spaced apart at varied distances along a direction parallel to the bottom surface of the second region 132b.

The material included in the second dislocation blocking layer 133b and the specific method of forming the second dislocation blocking layer 133b may be the same as those of the first dislocation blocking layer 133a, and therefore detailed descriptions may be omitted.

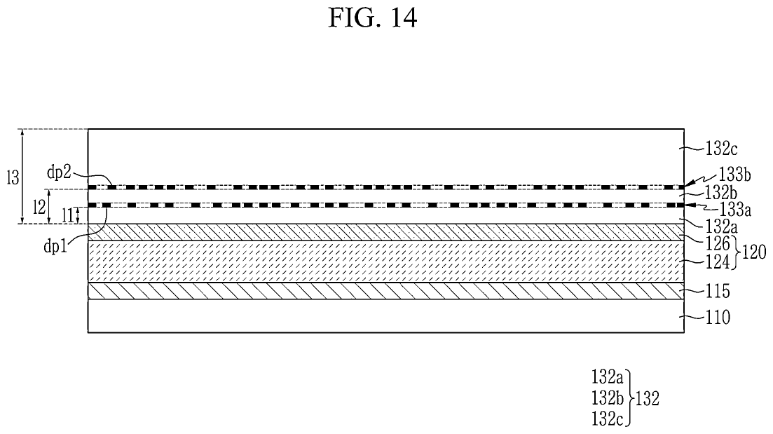

As shown in FIG. 14, the third region 132c of the channel layer 132 may be formed on the second region 132b and the second dislocation blocking layer 133b. The third region 132c may be formed between the second dislocation blocking patterns dp2. In one or more embodiments, the third region 132c may form the channel layer 132 together with the first region 132a and the second region 132b.

The third region 132c may be formed to a third level 13 with respect to the upper surface of the high-resistance layer 126. The third level 13 may be higher than the second level 12.

The third region 132c may include the same material as the first region 132a and the second region 132b. That is, the third region 132c may include may include one or more materials from Group III-V materials (for example, nitrides containing at least one of Al, Ga, In, or B). The material included in the third region 132c may be AlₓIn_{y}Ga_{1-x-y}N (0≤x≤1, 0≤y≤1, x+y≤1). For example, the third region 132c may include at least one of AlN, GaN, InN, InGaN, AlGaN, AlInN, and AlInGaN.

The third region 132c may be formed directly above the second region 132b and the second dislocation blocking layer 133b using an epitaxial growth method. The third region 132c may be grown in the same way as the second region 132b. In one or more embodiments, the third region 132c may be formed in-situ in the same process as the process forming the second region 132b and the second dislocation blocking layer 133b. Among the entire upper surface region of the second region 132b, a portion exposed between the second dislocation blocking patterns dp2 may be used as a seed to form the third region 132c. In other words, the material (e.g., GaN) included in the third region 132c may be grown from the upper surface of the second region 132b. However, the material (e.g., GaN) included in the third region 132c may not grow in an area covered by the second dislocation blocking patterns dp2. Accordingly, the material included in the third region 132c may not grow in the upward direction, but may grow in the lateral direction in a region adjacent to the second dislocation blocking patterns dp2. In this case, the direction in which dislocations contained within the third region 132c propagate may also change to the lateral direction.

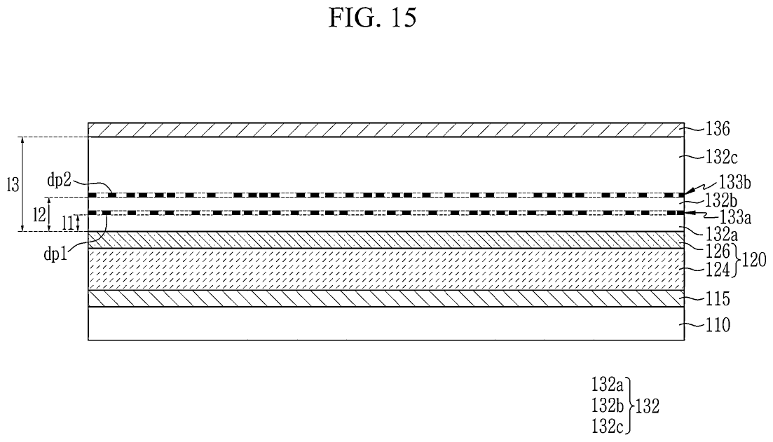

As shown in FIG. 15, the barrier layer 136 may be formed on the channel layer 132. The barrier layer 136 may be formed using an epitaxial growth method. The barrier layer 136 may include may include one or more materials from Group III-V materials (for example, nitrides containing at least one of Al, Ga, In, or B). The barrier layer 136 may be AlₓIn_{y}Ga_{1-x-y}N (0≤x≤1, 0≤y≤1, x+y≤1). For example, the barrier layer 136 may include at least one of AlN, GaN, InN, InGaN, AlGaN, AlInN, and AlInGaN. The barrier layer 136 may include a material having a different energy band gap than the channel layer 132. The barrier layer 136 may have a higher energy band gap than the channel layer 132.

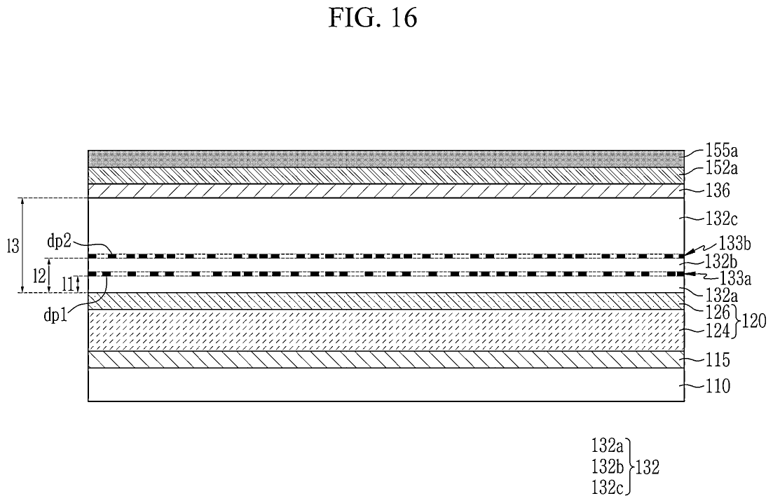

As shown in FIG. 16, a gate semiconductor material layer 152a and a gate electrode material layer 155a may be sequentially formed on the barrier layer 136.

The gate semiconductor material layer 152a may be continuously formed on the barrier layer 136 using an epitaxial growth method. The gate semiconductor material layer 152a may be formed of the same semiconductor material as the buffer layer 120, the channel layer 132, and the barrier layer 136. However, a material composition ratio of each layer may be different considering the role of each layer and the performance required for the semiconductor device. The gate semiconductor material layer 152a may include may include one or more materials from Group III-V materials (for example, nitrides containing at least one of Al, Ga, In, or B). The gate semiconductor material layer 152a may be AlₓIn_{y}Ga_{1-x-y}N (0≤x≤1, 0≤y≤1, x+y≤1). For example, the gate semiconductor material layer 152a may include at least one of AlN, GaN, InN, InGaN, AlGaN, AlInN, and AlInGaN.

In one or more embodiments, the gate semiconductor material layer 152a may include GaN and may be doped with impurity. The gate semiconductor material layer 152a may be doped with P-type impurity (for example, magnesium (Mg)).

The gate electrode material layer 155a may be formed on the gate semiconductor material layer 152a. The gate electrode material layer 155a may be formed using a deposition process. For example, the gate electrode material layer 155a may be formed using at least one of physical vapor deposition (PVD), thermal chemical vapor deposition (CVD), low pressure chemical vapor deposition (LP-CVD), plasma enhanced chemical vapor deposition (PE-CVD), or ALD technologies, but the semiconductor device is not limited thereto.

The gate electrode material layer 155a may include a conductive material. For example, the gate electrode material layer 155a may include a metal, a metal alloy, conductive metal nitride, metal silicide, a doped semiconductor material, a conductive metal oxide, or a conductive metal oxide. For example, the gate electrode material layer 155a may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbo-nitride (TiAlC—N), titanium aluminum carbide (TiAlC), titanium carbide (TiC), tantalum carbo-nitride (TaCN), tungsten (W), aluminum (Al), copper (Cu), cobalt (Co), titanium (Ti), tantalum (Ta), nickel (Ni), platinum (Pt), nickel platinum(Ni—Pt), niobium(Nb), niobium nitride(NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but the semiconductor device is not limited thereto. The gate electrode material layer 155a may be formed of a single layer or multiple layers.

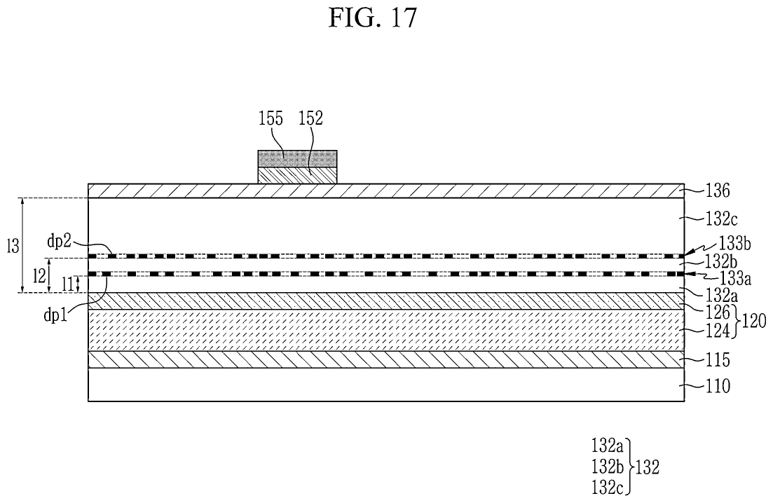

As shown in FIG. 17, the gate electrode 155 and the gate semiconductor layer 152 may be formed by patterning the gate electrode material layer 155a and the gate semiconductor material layer 152a using photo and etching processes.

For example, a hard mask layer and a photoresist layer may be formed sequentially on the gate electrode material layer 155a. A photoresist pattern may be formed by patterning the photoresist layer using a photo process. A hard mask pattern may be formed by etching the hard mask layer using the photoresist pattern as a mask. At least a portion of the gate electrode material layer 155a and a portion of the gate semiconductor material layer 152a may be removed by continuously etching the gate electrode material layer 155a and the gate semiconductor material layer 152a using the hard mask pattern as a mask. Accordingly, a remaining portion of the gate electrode material layer 155a may become the gate electrode 155. In addition, a portion of the gate semiconductor material layer 152a that remains may become the gate semiconductor layer 152. The gate electrode 155 may be in ohmic contact with the gate semiconductor layer 152.

The gate semiconductor layer 152 and the gate electrode 155 may have the same pattern by patterning the gate semiconductor material layer 152a and gate electrode material layer 155a using the same mask. That is, the gate semiconductor layer 152 and the gate electrode 155 may have the same planar shape. In a cross-sectional view, the gate semiconductor layer 152 and gate electrode 155 may have the same width. The gate electrode 155 may completely overlap the gate semiconductor layer 152 in the vertical direction, and the upper surface of the gate semiconductor layer 152 may be entirely covered by the gate electrode 155.

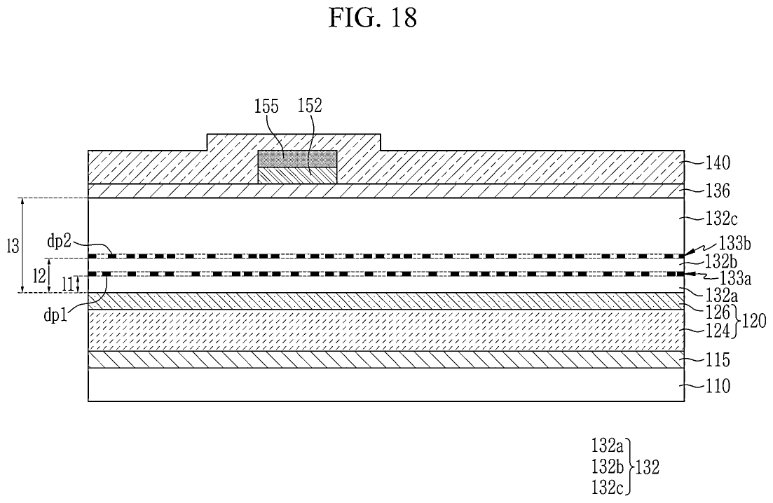

As shown in FIG. 18, a first protective layer 140 that covers the gate electrode 155, a portion of the upper surface of the barrier layer 136, and the side surface of the gate semiconductor layer 152 may be formed. The first protective layer 140 may include an insulating material. For example, the first protective layer 140 may include a material such as SiO₂, SiN, SiON, Al₂O₃, and the like. The first protective layer 140 is shown as a single layer, but in some cases, the first protective layer 140 may be formed of multiple layers. In this case, the first protective layer 140 may be formed by sequentially depositing different materials. Alternatively, the first protective layer 140 formed of several layers with different characteristics may be formed by using the same material while varying the deposition conditions. In particular, a portion of the first protective layer 140, adjacent to the barrier layer 136, may be formed of an insulating material of much better quality than other portions. This is to prevent electrons forming a channel from being trapped within the channel layer 132 disposed below the barrier layer 136. A portion of the first protective layer 140, which contacts the barrier layer 136, may be made of SiO₂.

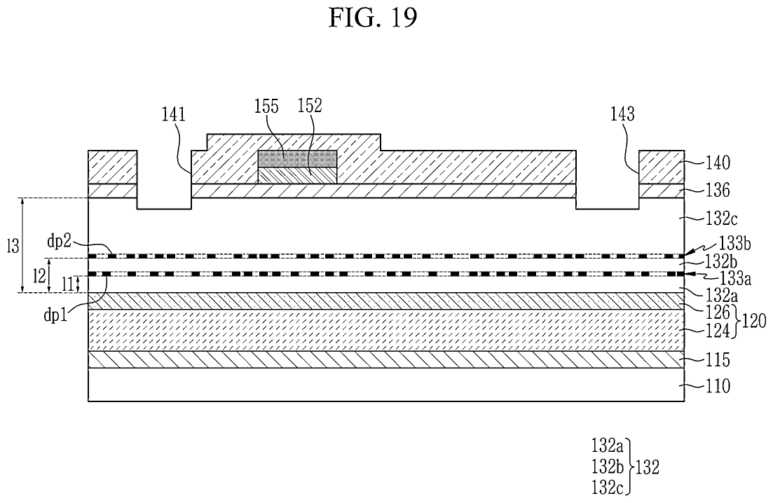

Next, as shown in FIG. 19, a first trench 141 and a second trench 143 may be formed by patterning the first protective layer 140. In this case, some regions of the barrier layer 136 and the channel layer 132 may be patterned together.

For example, a photoresist pattern may be formed on the first protective layer 140, and the first protective layer 140, the barrier layer 136, and the channel layer 132 may be sequentially etched using the photoresist pattern as a mask. In this case, the barrier layer 136 may be penetrated by the first trench 141 and the second trench 143, and the upper surface of the channel layer 132 may be penetrated by the trenches 141 and 143, such that recesses are formed on the upper surface of the channel layer 132. The channel layer 132 may be partially penetrated by the first trench 141 and the second trench 143. That is, a depth at which the upper surface of the channel layer 132 is recessed may be smaller than the entire thickness of the channel layer 132. For example, the depth at which the upper surface of the channel layer 132 is recessed may be less than about 30% of the entire thickness of the channel layer 132. In addition, the depth at which the upper surface of the channel layer 132 is recessed may be smaller than a thickness of the barrier layer 136. However, the semiconductor device is not limited thereto, and the depth at which the upper surface of the channel layer 132 is recessed may be changed in various ways. The side surface of the barrier layer 136 may be exposed to the outside by the first trench 141 and the second trench 143, and the upper and side surfaces of the channel layer 132 may be exposed. The channel layer 132 may form bottom surfaces and sidewalls of the first trench 141 and the second trench 143, and the barrier layer 136 may form the sidewalls of the first trench 141 and the second trench 143.

The first trench 141 and the second trench 143 may be spaced apart from each other. The first trench 141 and the second trench 143 may be disposed on both sides of the gate electrode 155. The first trench 141 may be disposed on one side of the gate electrode 155 to be spaced apart from the gate electrode 155. The second trench 143 may be disposed on the other side of the gate electrode 155 to be spaced apart from the gate electrode 155. A distance that separates the first trench 141 from the gate electrode 155 may be smaller than a distance that separates the second trench 143 from the gate electrode 155. The shapes, such as a width, a depth, and the like, of the first trench 141 and the second trench 143 are shown to be similar, but are not limited thereto. The shapes of the first trench 141 and the second trench 143 may be changed in various ways.

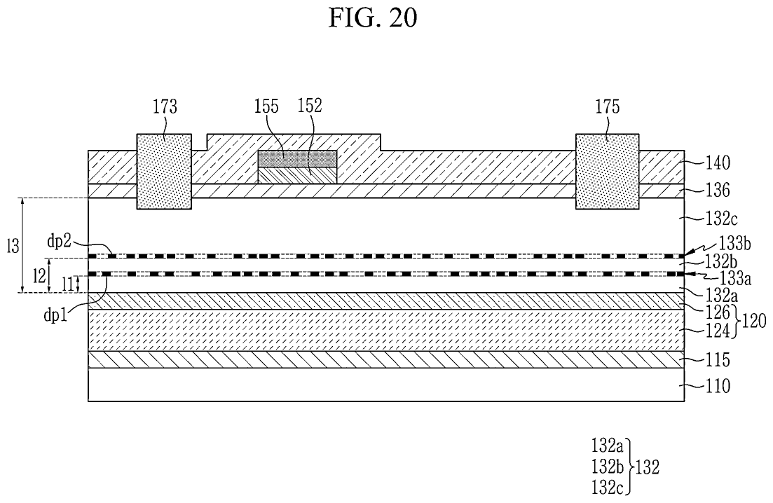

As shown in FIG. 20, a conductive material may be deposited on the first protective layer 140 on which the first trench 141 and the second trench 143 are formed, and patterned to form the source electrode 173 and the drain electrode 175.

The source electrode 173 and the drain electrode 175 may include a conductive material. For example, the source electrode 173 and the drain electrode 175 may include a metal, a metal alloy, conductive metal nitride, metal silicide, a doped semiconductor material, a conductive metal oxide, or a conductive metal oxide. The source electrode 173 and the drain electrode 175 may be formed of a single layer or multiple layers. For example, a plurality of conductive layers containing different materials may be stacked and then patterned to form the source electrode 173 and the drain electrode 175. In this case, the plurality of conductive layers may be etched simultaneously or sequentially using one mask pattern. For example, the source electrode 173 and the drain electrode 175 may be formed by sequentially stacking Ti, Al, Ti, and TiN and then patterning them. In this case, thicknesses of the four conductive layers constituting the source electrode 173 and the drain electrode 175 may be similar or different. For example, a layer made of Al may be relatively thick compared to other layers.

The source electrode 173 may be formed to fill the interior of the first trench 141. The source electrode 173 may contact the channel layer 132 and the barrier layer 136 in the first trench 141. The source electrode 173 may contact the side surfaces of the channel layer 132 and the barrier layer 136. The source electrode 173 may cover the side surfaces of the channel layer 132 and the barrier layer 136. The source electrode 173 may be electrically connected to the channel layer 132 through the first trench 141.

The drain electrode 175 may be formed to fill the interior of the second trench 143. The drain electrode 175 may contact the channel layer 132 and the barrier layer 136 in the second trench 143. The drain electrode 175 may contact the side surfaces of the channel layer 132 and the barrier layer 136. The drain electrode 175 may cover the side surfaces of the channel layer 132 and the barrier layer 136. The drain electrode 175 may be electrically connected to the channel layer 132 through the second trench 143.

The source electrode 173 and drain electrode 175 may be in ohmic contact with the channel layer 132. A region contacting the source electrode 173 and the drain electrode 175 within the channel layer 132 may be doped at a relatively high concentration compared to other regions. For example, the channel layer 132 may be doped by an ion implant process, annealing process, and the like. However, the semiconductor device is not limited thereto, and the doping process of the channel layer 132 may include various other processes. The doping process of the channel layer 132 may be performed before forming the source electrode 173 and drain electrode 175. In some cases, the channel layer 132 may not be doped.

A 2DEG 134 may be formed in a portion adjacent to the barrier layer 136 inside the channel layer 132. The 2DEG 134 may be disposed at an interface between the channel layer 132 and the barrier layer 136. The 2DEG 134 may be disposed in a drift region DTR between the source electrode 173 and the drain electrode 175. The depletion region DPR may be formed within the channel layer 132 by the gate semiconductor layer 152 having a different energy band gap from the barrier layer 136. Accordingly, the semiconductor device according to one or more embodiments may have a normally off characteristic. That is, the semiconductor device according to one or more embodiments may be a normally off HEMT. In a gate off state, the 2DEG 134 may be disposed in the drift region DTR excluding the depletion region DPR of the channel layer 132. In a gate on state, the flow of the 2DEG 134 continues within the depletion region DPR, allowing the entire 2DEG 134 to be disposed within the drift region DTR.

The semiconductor device may be classified according to materials, such as a SiC electric power semiconductor device, a GaN electric power semiconductor device, and the like. The semiconductor device may be manufactured using SiC or GaN instead of silicon (Si) wafers. The SiC electric power semiconductor device may have a low power loss due to its lower surface resistance to high temperatures and may be suitable for electric vehicles, renewable energy systems, and the like. The GaN electric power semiconductor device requires high costs, but are efficient in terms of speed and may be suitable for high-speed charging of mobile devices.

The semiconductor devices according to one or more embodiment may include irregularly arranged dislocation blocking patterns inside the channel layer, and accordingly, defect density inside the channel layer may be reduced, thereby improving the electrical characteristics and reliability of the semiconductor device.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device comprising:
a channel layer having a first energy band gap;
a barrier layer on the channel layer, the barrier layer comprising a material having a second energy band gap that is different from the first energy band gap of the channel layer;
a gate electrode on the barrier layer;
a gate semiconductor layer between the barrier layer and the gate electrode; and
at least one dislocation blocking layer in the channel layer, the at least one dislocation blocking layer comprising a plurality of dislocation blocking patterns extending in the channel layer and in a first direction parallel with a bottom surface of the channel layer,
wherein the plurality of dislocation blocking patterns are arranged at irregular intervals along the first direction.

2. The semiconductor device of claim 1, wherein each dislocation blocking pattern of the plurality of dislocation blocking patterns has a width in a range of about 0.5 nm to about 10 nm.

3. The semiconductor device of claim 1, wherein each dislocation blocking pattern of the plurality of dislocation blocking patterns has a height less than or equal to about 1 nm.

4. The semiconductor device of claim 1, wherein each dislocation blocking pattern of the plurality of dislocation blocking patterns comprises SiNₓ.

5. The semiconductor device of claim 1, wherein the plurality of dislocation blocking patterns are configured to block dislocations from extending to an upper surface of the channel layer such that at least one dislocation blocking pattern of the plurality of dislocation blocking patterns has a bottom surface contacting one end of a dislocation extending from the bottom surface of the channel layer.

6. The semiconductor device of claim 1, wherein the at least one dislocation blocking layer comprises:
a first dislocation blocking layer comprising first dislocation blocking patterns of the plurality of dislocation blocking patterns at a first level in the channel layer; and
a second dislocation blocking layer comprising second dislocation blocking patterns of the plurality of dislocation blocking patterns at a second level in the channel layer that is higher than the first level.

7. The semiconductor device of claim 1, wherein a distance between an upper surface of at least one dislocation blocking pattern of the plurality of dislocation blocking patterns and an upper surface of the channel layer is in a range of about 50 nm to about 450 nm.

8. The semiconductor device of claim 1, wherein each dislocation blocking pattern of the plurality of dislocation blocking patterns has a plate-like shape comprising a flat upper surface.

9. A method of manufacturing a semiconductor device, comprising:
forming a channel layer on a substrate, the channel layer having a first energy band gap;
forming a barrier layer on the channel layer, the barrier layer comprising a material with a second energy band gap that is different from the first energy band gap of the channel layer;
forming a gate semiconductor layer on the barrier layer; and
forming a gate electrode on the gate semiconductor layer,
wherein the forming the channel layer comprises,
forming a dislocation blocking layer in the channel layer, the dislocation blocking layer comprising a plurality of dislocation blocking patterns extending in a first direction parallel with a bottom surface of the channel layer and arranged at irregular intervals along the first direction.

10. The method of claim 9, wherein the dislocation blocking layer is formed in the channel layer in-situ during a process for forming the channel layer.

11. The method of claim 9, wherein the forming the channel layer further comprises:
forming the channel layer to a first level;
forming a first dislocation blocking layer on the channel layer at the first level, the first dislocation blocking layer comprising first dislocation blocking patterns of the plurality of dislocation blocking patterns;
forming the channel layer to a second level that is higher than the first level;
forming a second dislocation blocking layer on the channel layer at the second level, the second dislocation blocking layer comprising second dislocation blocking patterns of the plurality of dislocation blocking patterns; and
forming the channel layer to a third level that is higher than the second level.

12. The method of claim 9, wherein each dislocation blocking pattern of the plurality of dislocation blocking patterns has a width in a range of about 0.5 nm to about 10 nm.

13. The method of claim 9, wherein each dislocation blocking pattern of the plurality of dislocation blocking patterns has a height less than or equal to about 1 nm.

14. The method of claim 9, wherein each dislocation blocking pattern of the plurality of dislocation blocking patterns comprises SiNₓ.

15. The method of claim 9, wherein at least one dislocation blocking pattern of the plurality of dislocation blocking patterns has a bottom surface contacting one end of a dislocation extending from the bottom surface of the channel layer.

16. The method of claim 9, wherein a distance between an upper surface of at least one dislocation blocking pattern of the plurality of dislocation blocking patterns and an upper surface of the channel layer is in range of about 50 nm to about 450 nm.

17. The method of claim 9, wherein each dislocation blocking pattern of the plurality of dislocation blocking patterns has a plate-like shape comprising a flat upper surface.

18. A semiconductor device comprising:
a substrate;
a buffer layer on the substrate;
an ultra-lattice layer on the buffer layer;
a high-resistance layer on the ultra-lattice layer and comprising carbon-doped GaN;
a channel layer on the high-resistance layer, the channel layer comprising GaN and having a first energy band gap;
a barrier layer on the channel layer, the barrier layer comprising AlGaN and having a second energy band gap that is different from the first energy band gap of the channel layer;
a gate electrode on the barrier layer;
a gate semiconductor layer between the barrier layer and the gate electrode; and
at least one dislocation blocking layer in the channel layer and comprising a plurality of dislocation blocking patterns extending in a first direction parallel with a bottom surface of the channel layer,
wherein the plurality of dislocation blocking patterns are arranged at irregular intervals along the first direction, and
wherein each dislocation blocking pattern of the plurality of dislocation blocking patterns has a width in a range of about 0.5 nm to about 10 nm.

19. The semiconductor device of claim 18, wherein the at least one dislocation blocking layer further comprises:
a first dislocation blocking layer comprising first dislocation blocking patterns of the plurality of dislocation blocking patterns at a first level in the channel layer; and
a second dislocation blocking layer comprising second dislocation blocking patterns of the plurality of dislocation blocking patterns at a second level in the channel layer that is higher than the first level.

20. The semiconductor device of claim 18, wherein an upper surface of each dislocation blocking pattern of the plurality of dislocation blocking patterns comprises a flat plate shape.
